(19) United States
(12) Patent Application Publication
(10) Pub. No.: US 2026/0255720 A1
(43) Pub. Date: Aug. 27, 2026

(54) BACKSIDE-CONTACT SOLAR CELL AND METHOD FOR PRODUCING A BACKSIDE-CONTACT SOLAR CELL

(71) Applicant: Erik HOFFMANN, Stuttgart (DE)

(72) Inventor: Erik HOFFMANN, Stuttgart (DE)

(73) Assignee: Silfab Solar Cells SC Inc., Fort Mills, SC (US)

(21) Appl. No.: 19/530,422

(22) Filed: Feb. 5, 2026

(30) Foreign Application Priority Data
Feb. 27, 2025 (DE) 1020251074836

(51) Int. Cl. H10F 77/20

(52) U.S. Cl. CPC H10F 77/219

(57) ABSTRACT

A back-contact solar cell and a method for manufacturing a back-contact solar cell are disclosed. The back-contact solar cell includes a semiconductor substrate with a front side and a back side, first electrodes, and second electrodes. The back side has first regions, second regions, and third regions. The first regions are on a pedestal-like elevation and include a first tunnel layer, a first conductive layer, a conductive etch barrier layer, and a second conductive layer. the second regions comprise a second tunnel layer and a second conductive layer. the first regions and the second regions each form passivating contacts. the third regions comprise under-etched regions of the conductive etch barrier layer. each first electrode is in a first region and contacts a second conductive layer, and each second electrode is in a second region and contacts the second conductive layer.

### CROSS-REFERENCE TO RELATED APPLICATIONS

This application claims priority to German Pat. Appl. No. 10 2025 107 483.6, filed on Feb. 27, 2025, the contents of which are incorporated by reference herein in its entirety.

### FIELD OF THE INVENTION

The invention relates to a back-contact solar cell with features as described herein and a method for manufacturing a back-contact solar cell with such features.

### DISCUSSION OF THE BACKGROUND

In a back-contact solar cell, electrodes of opposite polarities, as well as emitter regions and base regions, are arranged on the back side of the solar cell. The back side of the solar cell is the side facing away from the sun during the operation of the solar cell. Accordingly, the front side of the solar cell is the side facing the sun.

Back-contact solar cells can generally achieve a higher efficiency than solar cells in which electrodes of one polarity are on the front side and electrodes of the opposite polarity are on the back side. In back-contact solar cells, the front side is not shaded by electrodes. To minimize resistance and recombination losses in back-contact solar cells, the electrodes of bothng polarities, as well as the emitter and base regions, alternate on the back side, with a small gap between the different regions.

Generating a large number of p-n junctions with small spacing is technically significantly more challenging than, for example, a conventional solar cell with a large-area, bilateral contact p-n junction. The alternating emitter and base regions on the back side can be realized, for instance, using laser irradiation. In this process, n-type and p-type dopants are locally introduced into a semiconductor substrate by temporally and spatially separated melting of the surface with laser irradiation, thereby creating either a p-type or n-type doped region depending on the dopant. Such a laser doping method is disclosed, for example, in DE 10 2013 219 564 A1. The described structuring of the back side allows for efficiencies of up to 24% due to low internal series resistances and high current yields.

Even higher efficiencies are essentially limited by recombination mechanisms in the base as well as at the heavily-doped contact and non-contact surfaces. Recombination in the base depends on the quality of the semiconductor substrate, and can be influenced only to a limited extent in the manufacturing process of the solar cell. Recombination mechanisms at the doped n-type and p-type surfaces are limited in the non-contact areas by Auger recombination only when there is good surface passivation, with Auger recombination increasing with the dopant concentration in silicon. In contact areas, where metal electrodes contact silicon, the contact with the metal leads to high interface recombination. During the manufacturing process, Auger recombination at the non-contact surfaces can be reduced by minimizing doping. However, a high dopant concentration is advantageous at the contact surfaces, as this reduces contact resistance and interface recombination.

To address this discrepancy, the use of so-called passivating or charge carrier-selective contacts is known, as seen in, for example, DE 10 2013 219 564 A1 or WO 2014/100004 A1. The electrodes do not directly contact the crystalline silicon wafer, which serves as an light absorber, but are separated by a thin dielectric layer, such as a silicon oxide layer or by an undoped hydrogenated amorphous silicon layer (a-Si:H). The passivation layer passivates the silicon surface on the one hand. On the other hand, the passivation layer is so thin that charge carriers (particularly electrons) can tunnel through the passivation layer from the semiconductor to the electrode, or from the electrode to the semiconductor (depending on the polarity). Therefore, the passivation layer can be referred to as a tunneling layer through which charge carriers can tunnel. The tunneling layer may also have small holes, e.g., in the nanometer (nm) range, that can allow for current flow.

In order to excite only one type of charge carrier to tunnel through the tunneling layer, depending on the polarity of the electrode, band bending may be useful. For example, band bending in silicon can be generated by a highly doped conductive layer, such as an n-type or p-type doped silicon layer, on the passivation layer. Doping this highly doped conductive layer above the passivation layer leads to band bending in the silicon substrate below the passivation layer. Therefore, classical doping of the silicon base to create a p-n junction is no longer necessary. Since the silicon substrate is no longer doped or only slightly doped, Auger recombination in the substrate decreases. The spatial separation of the metal/silicon interface of the electrodes from the silicon substrate also reduces interface recombination. Nevertheless, a low contact resistance can be achieved because the electrodes contact the heavily doped silicon layer. Doped silicon layers, for example, include amorphous, partially crystalline, or polycrystalline silicon layers or silicon carbide layers with a thickness of 20 nm to 400 nm, which can be deposited using methods such as PECVD, LPCVD, APCVD, or PVD.

Back-contact solar cells with charge carrier-selective contacts of opposite polarities have so far achieved an efficiency of up to 26.7%. However, the production of such solar cells is very complicated, as the two differently-doped passivating contacts are generally made using various complex masking and fabrication steps. High precision and fine resolution of the masking and fabrication have been employed. The distance between the charge carrier-selective contacts of opposite polarities should not exceed the diffusion length of the free charge carriers. However, large distances between the charge carrier-selective contacts can also lead to an increase in internal series resistance due to lateral current flow in the base.

The differently-doped silicon layers of the charge carrier-selective contacts can also be separated either by an undoped silicon layer or by a spatial separation (e.g., a trench or a break). Without such separation, the transition between the differently-doped layers may have a defect-rich p-n junction, which limits the efficiency of the solar cell. Ideally, the separation should be as fine (small) as possible, as a large area for separation can adversely affect the short-circuit current and the open-circuit voltage.

This “Discussion of the Background” section is provided for background information only. The statements in this “Discussion of the Background” are not an admission that the subject matter disclosed in this “Discussion of the Background” section constitutes prior art to the present disclosure, and no part of this “Discussion of the Background” section may be used as an admission that any part of this application, including this “Discussion of the Background” section, constitutes prior art to the present disclosure.

### SUMMARY OF THE INVENTION

It is therefore an object of the present invention to provide a back-contact solar cell and a method for manufacturing a back-contact solar cell, whereby the solar cell has a high efficiency and can be produced cost-effectively and efficiently.

This object is provided by a back-contact solar cell with features as described herein. The back-contact solar cell comprises a semiconductor substrate with a front side and a back side. The front side of the semiconductor substrate may form a front side of the solar cell. The back side of the semiconductor substrate may form a back side of the solar cell. The semiconductor substrate may include or consist essentially of silicon. The semiconductor substrate may be or comprise a silicon wafer.

The back of the semiconductor substrate (or the solar cell) includes a plurality of first regions, a plurality of second regions, and a plurality of third regions. The first regions include a layer stack comprising a first tunnel layer, a first conductive layer, a conductive etch barrier layer, optionally a second tunnel layer, and a second conductive layer. In the first regions, the first tunnel layer may be on the semiconductor substrate, while the remaining layers of the layer stack in the first regions may be in the aforementioned order. The second regions include a layer stack is comprising a second tunnel layer and the second conductive layer. In the second regions, the second tunnel layer may be on the semiconductor substrate, and the second conductive layer may be on the second tunnel layer. The third regions can, in particular, be free of both the first conductive layer and the second conductive layer.

The solar cell comprises a plurality of first electrodes and a plurality of second electrodes. Each first electrode is in a corresponding first region and contacts the second conductive layer. Each second electrode is in a corresponding second region and contacts the second conductive layer. The first regions are each on a pedestal-like elevation.

The pedestal-like elevations can comprise parts of the etched semiconductor substrate, the first tunnel layer, the first conductive layer, the conductive etch barrier layer, the second tunnel layer, the second conductive layer, and/or the passivation layer, provided that these layers are present in the solar cell.

Each pedestal-like elevation may have a cross-section that expands (i.e., becomes larger) at least partially, and optionally completely, in a first direction. Each pedestal-like elevation may alternatively have a cross-section that narrows at least partially, and optionally completely, in the first direction. Each pedestal-like elevation may have a cross-section that remains at least partially, and optionally completely, constant in the first direction. In particular, the pedestal-like elevations may have a trapezoidal or rectangular cross-sectional shape. The pedestal-like elevations can take any desired shape, particularly when the pedestal-like elevations encompass the semiconductor substrate and the first conductive layer.

The first direction may refer to a direction pointing away from the back or backside surface of the semiconductor substrate or the solar cell. It is also conceivable that the first direction may be a direction toward the back of the semiconductor substrate or the solar cell. The first direction is particularly oriented perpendicular to the front and back of the semiconductor substrate or the solar cell.

This allows the third regions to be formed in a recessed area that widens transversely to the first direction, and thus essentially in the “shadow” (with respect to the first direction) of the first regions (in particular, of the conductive etch barrier layer). The first conductive layers in the first regions and the second conductive layers in the second regions, particularly the first and second regions, are therefore each separated from one another by the third regions. The third regions in particular form a step or space in the “shadow” of the first regions, especially of the conductive etch barrier layer. This makes it possible to implement separate differently-doped (e.g., complementary) charge-carrier-selective contacts with a fine separation of a few micrometers and high resolution without further elaborate structuring steps. This separation can prevent a p-n junction from forming between the first and second conductive layers, which would otherwise particularly limit the fill factor and, consequently, the efficiency. Thus, a solar cell with the highest possible efficiency can be realized, which is cost-effective and efficiently manufacturable.

The second regions can be free of under-etching. In other words, the second regions may not include under-etched areas.

The first conductive layers can be p-type (positive) or n-type (negative) layers. The second conductive layers can also be p-type or n-type layers, but are generally complementary to the first conductive layers.

The third regions can have an extension perpendicular to the first direction, the extension having a width in a range from 0.2 μm to 20 μm (micrometers), particularly in a range from 1 μm to 10 μm.

The first conductive layer can be or comprise a doped silicon layer. The second conductive layer can also be or comprise a doped silicon layer. The dopants of the first conductive layer and the second conductive layer can be different or opposite doping types (n-type or p-type).

The first tunnel layer can be or comprise as a passivation layer. The first tunnel layer can have a passivating effect. The first tunnel layer can serve for passivation.

The second tunnel layer can also be or comprise a passivation layer. The second tunnel layer can also have a passivating effect. The second tunnel layer can also serve for passivation.

The first tunnel layer and/or the second tunnel layer can be or comprise a dielectric layer, such as SiOx or SiON, and/or an intrinsic layer, such as amorphous silicon, for example.

According to a further embodiment of the solar cell, the third regions can be undoped.

In this context, “undoped” refers to a lack of additional (process-related) doping, meaning the deliberate introduction of a significant amount of dopant. An undoped layer has the same or lower dopant concentration as the semiconductor substrate. The semiconductor substrate may have a low doping, for example in the range of 5×10¹⁶ cm⁻³. An “undoped” layer can thus have the same low doping as the semiconductor substrate. Accordingly, “doping” refers to an additional doping, compared to the semiconductor substrate. If an intrinsic amorphous silicon layer is used as a passivation layer (e.g., as a tunneling layer), it can differ from the semiconductor substrate, especially from “undoped” silicon.

As a result, the third regions can be implemented simply. In particular, this allows for a clear (undoped) separation between the first regions and the second regions.

According to one embodiment, the third regions can have a third conductive layer. The surface of the semiconductor substrate in the area of the third regions can thus be doped.

This can further improve the efficiency of the solar cell.

According to one embodiment of the solar cell, a fourth conductive layer can be on the front side of the semiconductor substrate or the solar cell. The fourth conductive layer can be a deposited layer, that is, a layer produced by deposition. It is also conceivable that the fourth conductive layer is not a deposited layer, but is produced by doping the semiconductor substrate or its surface.

This can further improve the efficiency of the solar cell.

According to an even further embodiment of the solar cell, the semiconductor substrate, the first conductive layers, the second conductive layers, the third conductive layers (or third regions) and/or the fourth conductive layer may have a doping according to one of the combinations in Table 1 below:

TABLE 1

| | | | Third | Front side |
|---|---|---|---|---|
| | First | Second | conductive | or fourth |
| Semiconductor | conductive | conductive | layer or | conductive |
| substrate | layer | layer | third region | layer |
| N | n | p | — | p |
| N | n | p | — | n |
| N | n | p | p | p |
| N | n | p | n | n |
| N | p | n | — | p |
| N | p | n | — | n |
| N | p | n | p | p |
| N | p | n | n | n |
| P | n | p | — | p |
| P | n | p | — | n |
| P | n | p | p | p |
| P | n | p | n | n |
| P | p | n | — | p |
| P | p | n | — | n |
| P | p | n | p | p |
| P | p | n | n | n |
| P | n | p | — | — |
| P | n | p | — | — |
| P | n | p | p | — |
| P | n | p | n | — |
| P | p | n | — | — |
| P | p | n | — | — |
| P | p | n | p | — |
| P | p | n | n | — |
| N | n | p | — | — |
| N | n | p | — | — |
| N | n | p | p | — |
| N | n | p | n | — |
| N | p | n | — | — |
| N | p | n | — | — |
| N | p | n | p | — |
| N | p | n | n | — |

In this document, and in particular in Table 1, “p” refers to an additional positive (or p-type) doping compared to the semiconductor substrate, “n” refers to an additional negative (or n-type) doping compared to the semiconductor substrate, and “-” means no additional doping compared to the semiconductor substrate.

This allows the solar cell to be designed and implemented as flexibly as possible.

According to a further embodiment of the solar cell, the first conductive layers, the second conductive layers, the first tunnel layers, and/or the second tunnel layers can each have no or substantially no perforations. The first tunnel layers and/or the second tunnel layers can each be continuous layers. In particular, the first tunnel layers and/or the second tunnel layers are not penetrated by the first electrodes and/or the second electrodes.

This can further improve the efficiency of the solar cell.

According to an embodiment of the solar cell, the first conductive layers, the second conductive layers, the third conductive layers, and/or the fourth conductive layer can each be or comprise silicon, silicon carbide, and/or a conductive metal oxide.

This allows the respective layers to be implemented simply. The efficiency of the solar cell can be further improved.

According to an embodiment of the solar cell, the first conductive layers and/or the second conductive layers can each be amorphous, semi-crystalline, or polycrystalline. The first conductive layers and/or the second conductive layers can thus, in particular, differ from the semiconductor substrate, which can be crystalline, especially monocrystalline. The third conductive layers, in particular, can have a morphology other than amorphous, semi-crystalline, or polycrystalline. In particular, the third conductive layers can be free of amorphous, semi-crystalline, or polycrystalline silicon.

This makes it possible to implement the respective layers simply. The efficiency of the solar cell can be further improved.

According to an embodiment of the solar cell, the second conductive layers can cause band bending in the semiconductor substrate. An additional conductive layer can be on the second conductive layers, the additional conductive layer having a higher conductivity than the respective second conductive layer underneath, to improve conductivity.

If the second conductive layers, which create the band bending in the semiconductor substrate, are not sufficiently conductive, an additional, more conductive layer can be applied to the second conductive layers to increase conductivity. For example, a metal oxide layer, a metal layer, or a titanium nitride layer can be on the second conductive layer, as is conventionally implemented sometimes in a heterojunction solar cell.

According to an embodiment of the solar cell, the etch barrier layer can be or comprise a metal, metal oxide, titanium nitride, or silicon carbide. It is also conceivable that the etch barrier layer can be or comprise another material that is conductive and etch-resistant.

This allows the conductive etch barrier layer to be implemented simply.

According to an embodiment of the solar cell, a dielectric layer or a dielectric layer stack can be on the front side of the semiconductor substrate or the solar cell as the outermost layer.

This allows for simple implementation of front-side passivation.

According to an embodiment of the solar cell, a dielectric layer or a dielectric layer stack can also be on the back of the semiconductor substrate or the solar cell. The dielectric layer or dielectric layer stack on the back of the semiconductor substrate or solar cell may be the outermost layer, other than the first and second electrodes. The dielectric layer or the dielectric layer stack on the back of the semiconductor substrate or solar cell can each comprise a first discontinuity in the region of the first areas and a second discontinuity in the region of the second areas. Each first electrode can contact a corresponding second conductive layer through a corresponding first discontinuity. Each second electrode can contact a corresponding second conductive layer through a corresponding second discontinuity.

This allows passivation and back-side contacts to be implemented simply.

The above-mentioned problem(s) may also be solved by a method for producing a back-contact solar cell according to the description(s) herein. The method includes:

Forming a first tunnel layer on a back side of a semiconductor substrate.

Forming a first conductive layer on the first tunnel layer.

Forming a conductive etch barrier layer on the first conductive layer. In this case, the conductive etch barrier layer may have interruptions in a plurality of etching areas. Alternatively, the method may comprise removing the conductive etch barrier layer in a plurality of etching areas, after forming the conductive etch barrier layer.

Etching in the etching areas and at least partially undercutting the conductive etch barrier layer, thereby creating pedestal-like elevations and a plurality of third regions. The third regions are underetched regions. The conductive etch barrier layer is not removed during etching, and optionally not after etching. Etching in the etching areas can comprise either wet chemical etching or dry etching.

Forming a second tunnel layer, particularly in areas between the pedestal-like elevations.

Forming a second conductive layer, particularly in the areas between the pedestal-like elevations, especially in the etching areas, without forming the second conductive layer in the third areas, due to the conductive etch barrier layer. The third areas can be in the “shadow” (with respect to the first direction) of the etch barrier layer. The third areas can be shadowed by the etch barrier layer, so that the second conductive layer is not formed or deposited in the third areas.

With regard to the advantages achievable with the method, reference is made to the corresponding statements concerning the solar cell. For further embodiments of the method, the details described in connection with the solar cell and/or those further explained below can be used.

According to an embodiment of the method, the method may further include forming a third conductive layer in the third regions and/or a fourth conductive layer on a front side of the substrate by means of furnace diffusion.

According to an embodiment of the method, the method may further include removing a silicate glass layer formed during the furnace diffusion (for example, a phosphosilicate glass or a borosilicate glass), in particular by (wet chemical) etching.

According to an embodiment of the method, the method may further include forming a dielectric layer or a stack of dielectric layers on the front side and/or the back side of the substrate.

According to a further embodiment of the method, the method may further include forming first electrodes and/or second electrodes (e.g., as described herein).

The process may, in particular, include anisotropically or isotropically etching the first conductive layer, the first tunneling layer, and/or the semiconductor substrate. Such etching can be carried out after depositing or growing the first tunneling layer, the first conductive layer, after depositing or otherwise forming the etch-resistant conductive barrier layer with the etch areas therein (which, in the method, may be formed for example by laser irradiation). Such etching can, for example, remove approximately 0.5 μm to 20 μm (etch depth), particularly 1 μm to 10 μm, of silicon along the first direction (i.e., perpendicular to the surface). In this process, independent of whether etching is anisotropic or isotropic, under-etching occurs below the conductive etch barrier layer and, if applicable, under the first conductive layer (if it exhibits high etch resistance due to its chemical properties). On the other hand, if only the first conductive layer is etched, the etch depth can correspond to the thickness of the first conductive layer (e.g., 20 nm to 400 nm).

After growing or depositing the second tunnel layer, which passivates the surface of the semiconductor substrate exposed by etching, the second conductive layer can be deposited, particularly using a directional method, such as physical vapor deposition (PVD; e.g., sputtering, optionally through a collimator). Unlike common chemical vapor deposition methods (PECVD, LPCVD, APCVD), no or hardly any material is deposited across the first direction (i.e., on surfaces perpendicular to the deposition direction of the material). In particular, this prevents, or at least reduces, material from being deposited beneath or in the under-etched regions of the etch barrier layer (that is, directly underneath the shadowed areas). This allows for the formation of the third regions, which in particular have neither the first conductive layer nor the second conductive layer therein. A p-n junction therefore cannot form between the first and second conductive layers, but only between a conductive layer and the semiconductor substrate (silicon wafer). This allows for a high fill factor and a high efficiency to be achieved.

In other words, particularly when removing the first conductive layer by etching in the etched areas, isotropic or anisotropic under-etching of the etch barrier layer occurs. The deposition of the second conductive layer can be carried out using a physical, directional (e.g., unidirectional) gas-phase deposition. As a result, the second conductive layer is not deposited on all exposed surfaces on the backside of the semiconductor substrate or solar cell, but is at least interrupted in shaded and/or under-etched areas. Therefore, no additional process step is required to separate the first conductive layer in the first areas and the second, differently-doped conductive layer in the second areas. Furthermore, this separation (i.e., areas without the first and second conductive layers) extends over a width of up to a few micrometers (e.g., the sum of the etching depth and the under-etched region, or the width of the under-etched area). This allows for an ultrafine separation of charge carrier-selective contacts in the micrometer or sub-micrometer range.

### BRIEF DESCRIPTION OF THE DRAWINGS

Further features, details, and advantages of the invention appear from the wording of the claims as well as from the following description of exemplary embodiments with reference to the drawings, which show:

FIG. 1 shows a schematic cross-section of a back-contact solar cell according to a first embodiment;

FIG. 2 shows a schematic cross-section of the back-contact solar cell according to a second embodiment;

FIG. 3 shows a schematic cross-section of the back-contact solar cell according to a third embodiment;

FIG. 4 shows a schematic cross-section of the back-contact solar cell according to a fourth embodiment; and

FIGS. 5 to 10 show cross-sections of intermediate structures formed in an exemplary method for manufacturing a back-contact solar cell.

### DETAILED DESCRIPTION

Reference will now be made in detail to various embodiments of the invention, examples of which are illustrated in the accompanying drawings. While the invention will be described in conjunction with the following embodiments, it will be understood that the descriptions are not intended to limit the invention to these embodiments. On the contrary, the invention is intended to cover alternatives, modifications and equivalents that may be included within the spirit and scope of the invention as defined by the appended claims. Furthermore, in the following detailed description, numerous specific details are set forth in order to provide a thorough understanding of the present invention. However, it will be readily apparent to one skilled in the art that the present invention may be practiced without these specific details. In other instances, well-known methods, procedures, components, and circuits have not been described in detail so as not to unnecessarily obscure aspects of the present invention. Furthermore, it should be understood that the possible permutations and combinations described herein are not meant to limit the invention. Specifically, variations that are not inconsistent may be mixed and matched as desired.

The technical proposal(s) of embodiments of the present invention will be fully and clearly described in conjunction with the drawings in the following embodiments. It will be understood that the descriptions are not intended to limit the invention to these embodiments. Based on the described embodiments of the present invention, other embodiments can be obtained by one skilled in the art without creative contribution and are in the scope of legal protection given to the present invention.

Furthermore, all characteristics, measures or processes disclosed in this document, except characteristics and/or processes that are mutually exclusive, can be combined in any manner and in any combination possible. Any characteristic disclosed in the present specification, claims, Abstract and Figures can be replaced by other equivalent characteristics or characteristics with similar objectives, purposes and/or functions, unless specified otherwise.

In the following description and in the figures, corresponding components and elements are marked with the same reference signs. For better clarity, not all reference signs are shown in every figure.

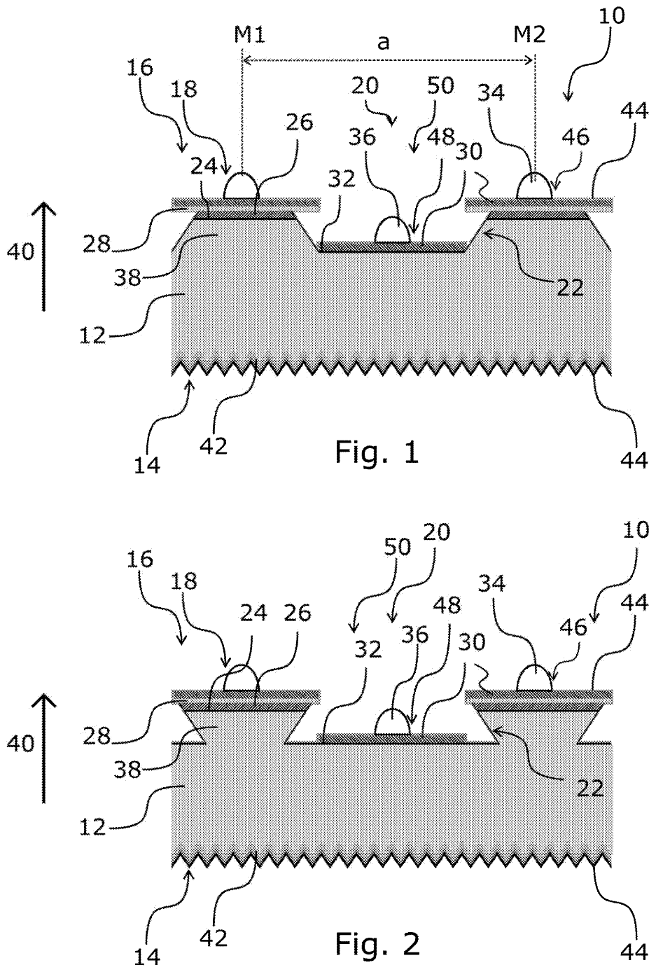

FIG. 1 shows a schematic cross-section of a back-contact solar cell 10 according to a first exemplary embodiment. In this example, the solar cell 10 comprises a crystalline n-type semiconductor substrate 12. The semiconductor substrate 12 here forms a silicon base, which serves as a light or solar energy absorber. In another embodiment, the semiconductor substrate 12 may alternatively be a crystalline p-type silicon substrate.

The semiconductor substrate 12 comprises a front side 14 and a back side 16. The front side 14 can form a front side of the solar cell 10. The back side 16 can form a back side of the solar cell 10. In operation, the front side 14 of the solar cell 10 is oriented toward the sun. In the illustrated embodiment, the front side 14 has a textured surface.

A plurality of first regions 18, a plurality of second regions 20, and a plurality of third regions 22 are on the back side 16.

A layer stack is in the first regions 18, in each case including a first tunnel layer 24, a first conductive layer 26, a conductive etch barrier layer 28, and a second conductive layer 30. It is conceivable that, in the first regions 18, a second tunnel layer 32 may be between the conductive etch barrier layer 28 and the second conductive layer 26. In the present case, the first tunnel layer 24 is on the semiconductor substrate 12, the first conductive layer 26 is on the first tunnel layer 24, the conductive etch barrier layer 28 is on the first conductive layer 26, and the second conductive layer 30 is on the conductive etch barrier layer 28.

A layer stack is also in the second regions 20, in each case including the second tunnel layer 32 and the second conductive layer 30. In the present case, the second tunnel layer 32 is on the semiconductor substrate 12, and the second conductive layer 30 is on the second tunnel layer 32.

The first regions 18 and the second regions 20 each include passivating contacts. The third regions 22 are under-etched areas of the first regions 18, in particular under the conductive etch barrier layer 28 and, when the first conductive layer 26 has a higher etch resistance than the crystalline wafer during etching to form the undercut areas, the first conductive layer 26.

The solar cell 10 comprises a plurality of first electrodes 34 and a plurality of second electrodes 36. Each first electrode 34 is in a corresponding one of the first regions 18 and contacts a corresponding second conductive layer 30. Each second electrode 36 is in a corresponding one of the second regions 20 and contacts a corresponding second conductive layer 30.

The first regions 18 are each on a pedestal-like elevation 38.

The first conductive layers 26 and/or the second conductive layers 30 can each be or comprise a doped silicon layer. The first conductive layers 26 and the second conductive layers 30 can each be amorphous, semi-crystalline, or polycrystalline. Consequently, they can differ from the semiconductor substrate, which can be crystalline (e.g., monocrystalline) and comprising or consisting essentially of silicon. The third regions 22 can each be free of amorphous, semi-crystalline, or polycrystalline silicon, as well as any other conducting or semiconducting materials.

The third regions 22 can be undoped. The third regions 22 can include a third conductive layer, which can have any morphology. The third conductive layer can be or comprise a doped surface of the semiconductor substrate 12.

The first conductive layers 26, the second conductive layers 30, the third conductive layers, and/or the fourth conductive layer 42 can each comprise or consist essentially of silicon, silicon carbide, and/or a conductive metal oxide.

The conductive etch barrier layer 28 can comprise or consist essentially of a conductive but etch-stable material, for example, a metal, a metal oxide (e.g., a conductive metal oxide), titanium nitride, or silicon carbide.

The second conductive layers 30 can cause band bending in the semiconductor substrate 12. An additional conductive layer, which has a higher conductivity than the second conductive layer 30, may be on each of the second conductive layers 30 in order to improve the conductivity of the structure overlying the semiconductor substrate 12 in the second regions 20.

A fourth conductive layer 42 can be on the front side 14. The fourth conductive layer 42 can be or comprise a doped silicon layer. This can include p-type doped silicon. The fourth conductive layer 42 can form a so-called “Front Floating Emitter” (FFE), an emitter with a p-n junction (i.e., with a doping opposite to that of the semiconductor substrate 12). The fourth conductive layer 42 can be doped with a p-type dopant, for example boron, in particular with a dopant concentration of approximately 5×10¹⁷ cm⁻³ to 1×10²⁰ cm⁻³, preferably about 5×10¹⁸ cm⁻³ to 5×10¹⁹ cm⁻³.

In another embodiment, an n-type doping, in particular with a comparable or identical dopant concentration, can also be provided. In this case, the doping on the front side 14 is referred to as a “Front Surface Field” (FSF), meaning a structure having a doping equal to that of the semiconductor substrate 12. The fourth conductive layer 42 can be doped with an n-type dopant, for example phosphorus, in particular with a dopant concentration of approximately 5×10¹⁷ cm⁻³ to 1×10²⁰ cm⁻³, preferably about 5×10¹⁸ cm⁻³ to 5×10¹⁹ cm⁻³.

A dielectric layer or a stack of dielectric layers 44 can be on the front side 14 as the outermost layer. In other words, the front side 14 can be covered with the dielectric layer or the stack of dielectric layers 44.

The dielectric layer or a dielectric layer stack 44 can also be on the back side 16 as the outermost layer (except for the electrodes 34 and 36), wherein the dielectric layer or the dielectric layer stack 44 on the back 16 comprises a first interruption 46 in each of the first regions 18 and a second interruption 48 in each of the second regions 20. Each first electrode 34 contacts a corresponding second conductive layer 30 through a first interruption 46. Each second electrode 36 contacts a corresponding second conductive layer 30 through a second interruption 48.

The first and/or second interruptions 46, 48 can, for example, be continuous or round, square, linear, or segmented interruptions. Accordingly, contact surfaces of the appropriate shape for the first and second electrodes 34, 36, such as point-shaped or circular contact surfaces, or linear or segmented contact surfaces, can be provided.

The dielectric layer or the dielectric layer stack 44 can passivate the front side 14 and/or the back side 16, reduce reflections on the front side 14, and improve the light absorption of the solar cell 10. The dielectric layer/stack 44 may comprise, for example, an aluminum oxide (AlOx, e.g. Al₂O₃), a silicon oxide (SiOx, e.g. SiO₂), and/or silicon nitride (SiNx, e.g. Si₃N₄). The dielectric layer 44 can be or comprise a layer stack (i.e., a plurality of layers). The layer stack can consist of two or more layers of, for example, AlOx, SiOx, and/or SiNx. Other layers for reducing reflection and/or improving passivation are also conceivable.

The dielectric layer or the dielectric layer stack 44 on the front side 14 and the dielectric layer or the dielectric layer stack 44 on the back side 16 may be constructed identically or differently.

In the present case, the dielectric layer 44 on the front side 14 may comprise two layers. The dielectric layer 44 on the back side 16 may comprise a single layer in some embodiments.

The semiconductor substrate 12, the first conductive layers 26, the second conductive layers 30, the third conductive layers, the fourth conductive layer 42, and/or the third regions 22 of the solar cell 10 may each have a doping type according to one of the combinations specified in Table 1 below.

TABLE 1

| | | | Third | Front side |
|---|---|---|---|---|
| | First | Second | conductive | or fourth |
| Semiconductor | conductive | conductive | layer or | conductive |
| substrate | layer | layer | third region | layer |
| n | n | p | — | p |
| n | n | p | — | n |
| n | n | p | p | p |
| n | n | p | n | n |
| n | p | n | — | p |
| n | p | n | — | n |
| n | p | n | p | p |
| n | p | n | n | n |
| p | n | p | — | p |
| p | n | p | — | n |
| p | n | p | p | p |
| p | n | p | n | n |
| p | p | n | — | p |
| p | p | n | — | n |
| p | p | n | p | p |
| p | p | n | n | n |
| p | n | p | — | — |
| p | n | p | — | — |
| p | n | p | p | — |
| p | n | p | n | — |
| p | p | n | — | — |
| p | p | n | — | — |
| p | p | n | p | — |
| p | p | n | n | — |
| n | n | p | — | — |
| n | n | p | — | — |
| n | n | p | p | — |
| n | n | p | n | — |
| n | p | n | — | — |
| n | p | n | — | — |
| n | p | n | p | — |
| n | p | n | n | — |

For example, a surface of the back side 16 may be textured or chemically polished over the entire area. The surface of the back side 16 may also include a combination of textured areas and polished areas. For instance, the surface in the first areas 18 may be polished, while the surface in the second areas 20 may be textured (or vice versa). Chemical polishing can include, for example, treatment of the surface by (or after) anisotropic silicon etching with hot (e.g., 80-100° C.) aqueous potassium hydroxide.

The first regions 18 and the second regions 20 may alternate side by side. A distance a between a center M1 of a first region 18 (which may be n-type doped) and a center M2 of the next first region 18 (which may also be n-type doped) is, for example, between 200 μm and 3000 μm or any value or range of values therein (e.g., between 400 μm and 2000 μm). Accordingly, a distance between a center of a second region 20 (which may be p-type doped) and a center of the next second region 20 (which may also be p-type doped) is, for example, between 200 μm and 3000 μm, preferably between 400 μm and 2000 μm.

Over the back side 16, the ratio of the total area of the p-type doped regions to the total area of the n-type doped regions may be between 1:9 and 9:1, especially from 2:8 to 8:2, and preferably from 3:7 to 7:3.

The alternating pattern of the first and second regions 18, 20 can in principle extend completely or at least approximately over the entire back side 16 of the semiconductor substrate 12 or solar cell 10. However, the alternating pattern can also be locally interrupted, for example, in areas that contain a current collecting rail or bus.

The thickness of the first conductive layers 26 and/or the second conductive layers 30 can, for example, range from 10 nm to 400 nm. The first conductive layers 26 and the second conductive layers 30 may have the same thickness. It is also conceivable that the first conductive layers 26 and the second conductive layers 30 may have different thicknesses.

The first conductive layers 26 and/or the second conductive layers 30 can be doped with an n-type dopant, e.g., phosphorus, and with a dopant concentration of, for example, 1×10¹⁹ cm⁻³ to 1×10²¹ cm⁻³, preferably from 5×10¹⁹ cm⁻³ to 2×10²¹ cm⁻³.

The first and/or second tunnel layers 24, 32 can each be or comprise a dielectric layer. The first and/or second tunnel layers 24, 32 can, for example, include a layer of silicon oxide (SiOx, e.g., undoped or thermally-grown SiO₂) or a layer of silicon oxynitride (SiON). The first and/or second tunnel layers 24, 32 can passivate the surface of the semiconductor substrate 12. The first and/or second tunnel layers 24, 32 can, for example, have a thickness of 0.5 nm to 4 nm. This especially enables tunneling of charge carriers.

The first and/or second tunnel layers 24, 32 can alternatively each be or comprise an intrinsic amorphous silicon layer. The amorphous silicon layer can be hydrogenated, i.e., saturated with hydrogen. The first and/or second tunnel layers 24, 32 can passivate the surface of the semiconductor substrate 12. The first and/or second tunnel layers 24, 32 can, for example, have a thickness of 0.5 nm to 20 nm. This can enable tunneling of charge carriers.

The first and/or second tunnel layers 24, 32 can each be free of breaks. It is also conceivable that the first and/or second tunnel layers 24, 32 may have openings (e.g., so-called pinholes) having a width or diameter in the nm range (e.g., 1-9 nm). This can enable ohmic contact between the semiconductor substrate 12 and the first conductive layer 26 or the second conductive layer 30.

The first conductive layers 26 and/or the second conductive layers 30 can each be without any detectable openings.

In the present invention, the first regions 18 and the second regions 20 are separated from one another by the third regions 22. The third regions 22 are or comprise an under-etched volume of the semiconductor substrate 12, the first tunnel layer 24, and the first conductive layer 26 (e.g., etched or removed silicon).

In the first embodiment illustrated in FIG. 1, the semiconductor substrate 12 is undoped in the third regions 22. Accordingly, the dopant concentration of the third regions 22 corresponds in particular to the dopant concentration of the semiconductor substrate 12. The surface of the third regions 22 can be covered or passivated by a dielectric layer, in particular by the second tunnel layer 32. Additionally or alternatively, the surface of the third regions 22 can be covered with the dielectric layer or a dielectric layer stack 44. For this purpose, the dielectric layer or dielectric layer stack 44, unlike the second conductive layer 30, can be non-oriented and can also encompass (e.g., be in) the third regions 22.

In the present invention, the elevations 38 each have a cross-section that tapers in a first direction 40 below to conductive etch barrier layer 28 (e.g., from the substrate 12 to the conductive etch barrier layer 28). In other words, the cross-section of the elevations 38 widens in the direction opposite to the first direction 40 starting from the conductive etch barrier layer 28. In the first region 18, the conductive etch barrier layer 28 can represent the maximum extension of the elevation 38 transverse to the first direction 40. Put differently, the conductive etch barrier layer 28 can represent the widest portion (with respect to the first direction) of the elevation 38.

In the present case, the first direction 40 is oriented away from the back side 16. The first direction 40 may be oriented perpendicular to one or more horizontal surfaces on the back side 16 and/or the front side 14. In FIG. 1, the first direction 40 is oriented from bottom to top.

The cross-section of the pedestal-like protrusions 38 can have a concave or convex shape (e.g., wall). The cross-section of the pedestal-like protrusions 38 can feature rounded corners and/or irregularities, e.g., a texture, on its walls or flanks.

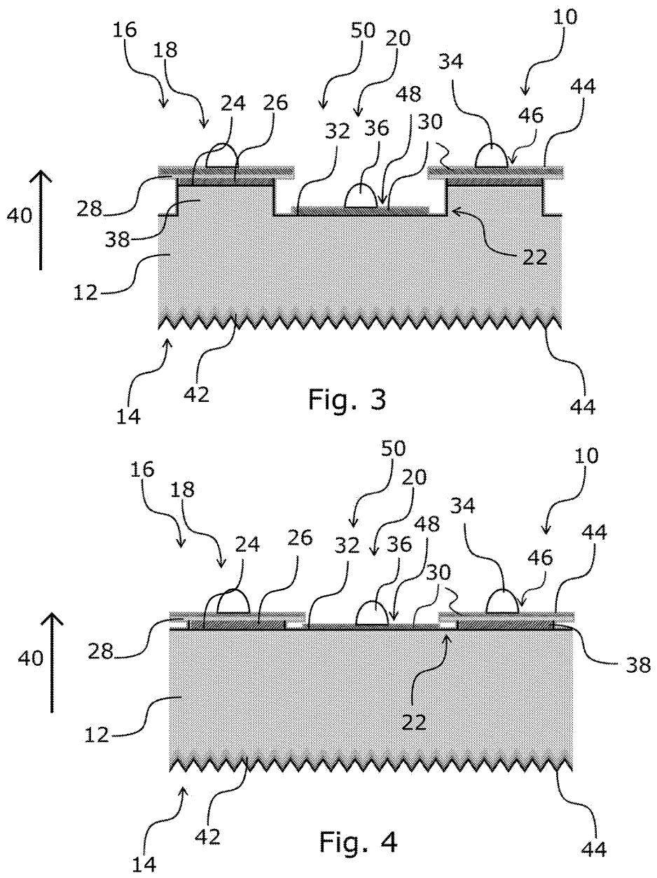

FIG. 2 shows a schematic cross-section of the back-contact solar cell 10 according to a second exemplary embodiment. The second exemplary embodiment differs from the first exemplary embodiment shown in FIG. 1 in the following ways.

Here, the protrusions 38 each have a cross-section that widens in the first direction 40, from the semiconductor substrate 12 up to the conductive etch barrier layer 28. In other words, the cross-section of the protrusions 38 tapers in the opposite direction to the first direction 40 from the conductive etch barrier layer 28. In this case, the first conductive layer 26 can also be undercut.

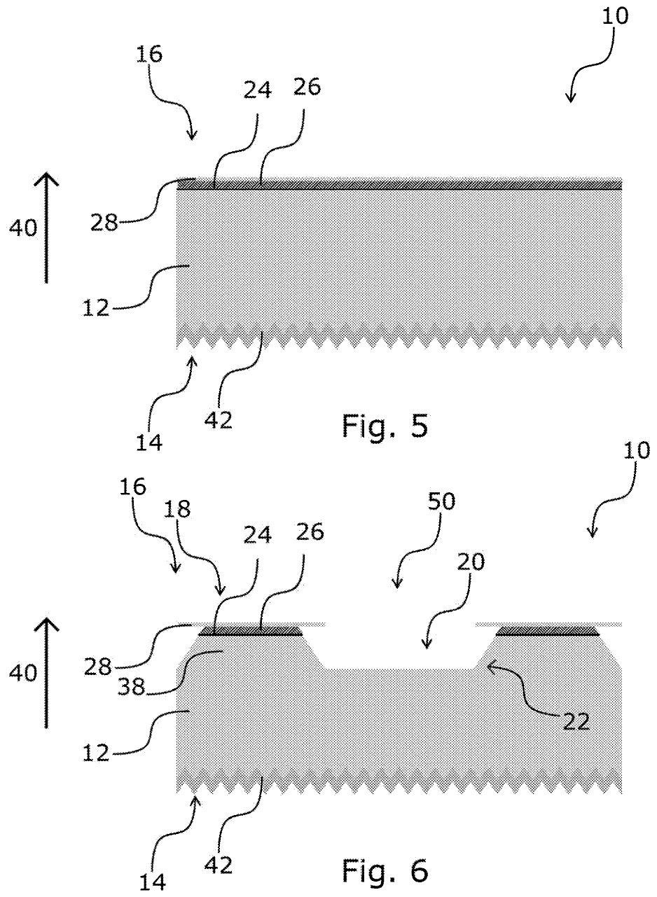

FIG. 3 shows a schematic cross-section of the back-contact solar cell 10 according to a third embodiment. The third embodiment differs from the first embodiment shown in FIG. 1 as follows.

In the embodiment shown in FIG. 3, the protrusions 38 each have a substantially uniform or constant width or cross-section in the first direction 40 up to the conductive etch barrier layer 28. In other words, the cross-sectional width of the protrusions 38 does not change along the first direction 40 up to the conductive etch barrier layer 28.

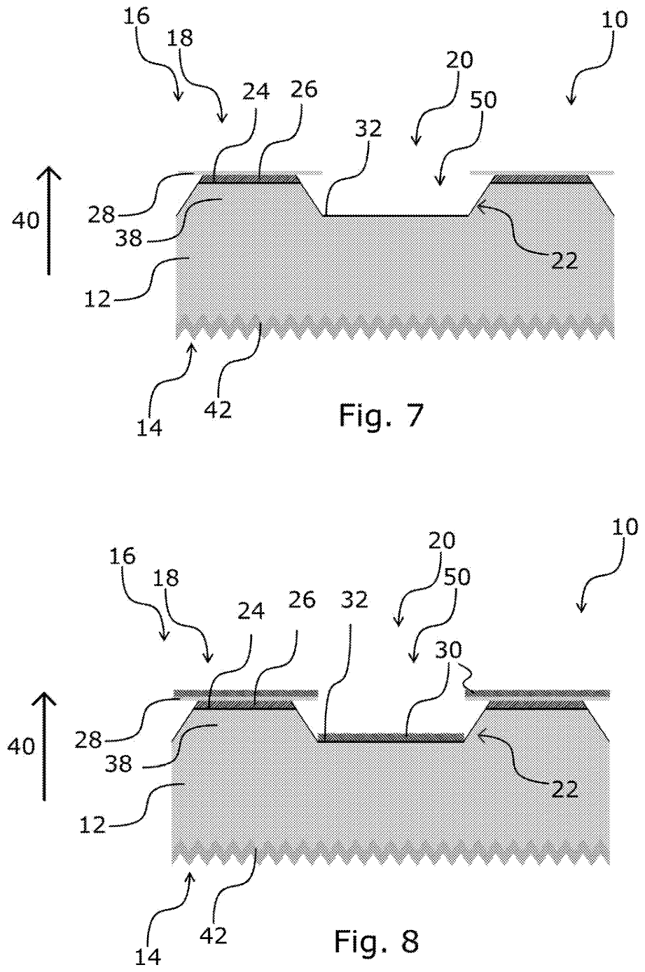

FIG. 4 shows a schematic cross-section of the back-contact solar cell 10 according to a fourth embodiment. The fourth embodiment differs from the third embodiment shown in FIG. 3 as follows.

The third regions 22 are here formed solely from a partially etched volume of the first conductive layer 26 and/or the first tunnel layer 24.

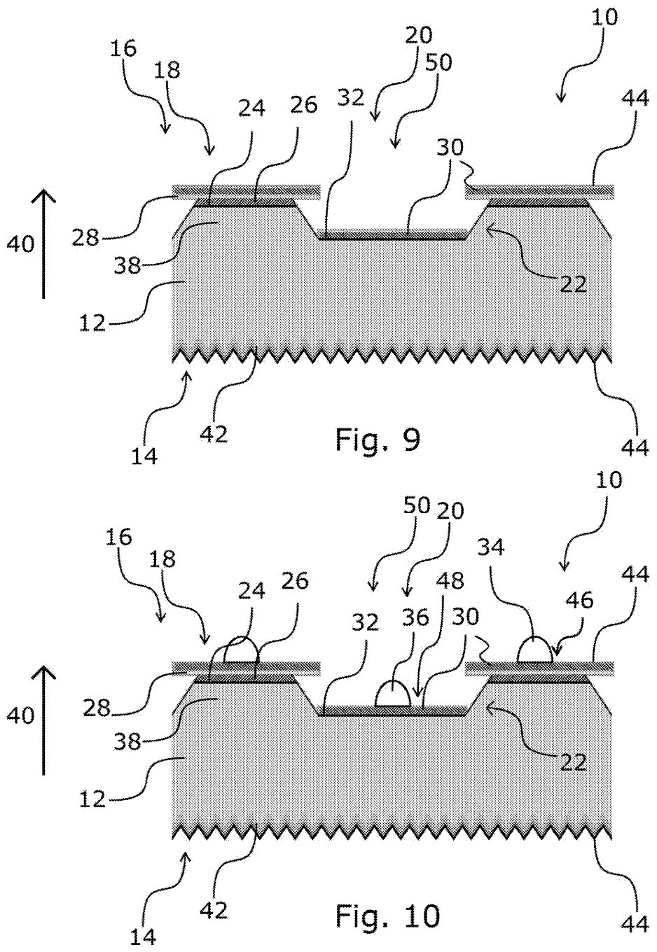

FIGS. 5 to 10 illustrate a method for manufacturing a back-contact solar cell 10. The solar cell 10 can be manufactured according to the above embodiments using the depicted method. The solar cell 10 may correspond to the solar cell 10 shown in FIGS. 1 to 4.

First, a semiconductor substrate 12 with a front side 14 and a back side 16 is provided. The front side 14 of the semiconductor substrate 12 may correspond to the front side of the solar cell 10. Accordingly, the back side 16 of the semiconductor substrate 12 may correspond to the back side of the solar cell 10.

The semiconductor substrate 12 can be textured using an isotropic etch, particularly on the front side 14 and the back side 16. An additional etch before texturing to remove saw damage is possible. Other methods for texturing are also conceivable.

The semiconductor substrate 12 can undergo a full-surface diffusion, for example a furnace diffusion, to dope the surfaces of semiconductor substrate 12, particularly on the front side 14 and the back side 16. This allows a fourth conductive layer 42 to be formed on the front side 14. The fourth conductive layer 42 can be doped with either a p-type or an n-type dopant, for example boron or phosphorus. This creates the fourth conductive layer 42 on the front side 14. Depending on the type of doping, the dopant forms a so-called “front floating emitter” or a “front surface field.”

During diffusion, for example, furnace diffusion, a dopant-rich silicate glass, such as borosilicate glass (BSG) or phosphosilicate glass (PSG), can be formed on the surface of the substrate 12 being doped. As a result, a silicate glass layer may be on the front side 14 and/or the back side 16 of the semiconductor substrate 12. On the back side 16 of the semiconductor substrate 12, the silicate glass layer is undesirable and should be completely or at least partially suppressed or removed after doping the substrate 12. This can be achieved by etching. In particular, for a solar cell 10 with a p-type semiconductor substrate 12, this diffusion step can also be skipped, so that the doping on the front side 14 of the semiconductor substrate 12 does not exceed the base doping of the semiconductor substrate 12. This can also apply to a solar cell 10 with an n-type semiconductor substrate 12.

A first tunnel layer 24 is formed on the backside 16 of the semiconductor substrate 12. This layer can be grown (e.g., thermally) or deposited. The thickness of the first tunnel layer 24 can range between 5 and 200 Angstroms. The first tunnel layer 24 can comprise or consist essentially of silicon oxide (e.g., undoped silicon dioxide). Other dielectric materials that serve surface passivation are also conceivable, provided they allow the passage of charge carriers. The first tunnel layer 24 can therefore be or comprise an a-Si:H layer. If necessary, the first tunnel layer 24 can also be grown or deposited on the front side 14. However, deposition on the front side 14 has little or no decisive impact on further processing, and may need to be removed if necessary, and is therefore not further considered.

The first conductive layer 26 is subsequently formed on the first tunnel layer 24. This can be achieved by deposition. The thickness of the first conductive layer 26 can range between 10 nm and 400 nm. The first conductive layer 26 may have a dopant concentration in a range from 1×10¹⁹ cm⁻³ to 2×10²¹ cm⁻³. The deposition of the first conductive layer 26 can be carried out, for example, by PVD or CVD (e.g., LPCVD, PECVD, or APCVD). In this process, deposition of the first conductive layer 26 may also occur at least partially at the edges on the front side 14 of the semiconductor substrate 12. The first conductive layer 26 can be doped in-situ during deposition, or initially deposited as an intrinsic layer and subsequently doped ex-situ. In ex-situ doping, the doping process may also affect the front side 14, and therefore a diffusion barrier may need to be present on the front side 14, especially if the types of dopants of the first conductive layer 26 and the fourth conductive layer 42 are opposite or complementary. If the first conductive layer 26 is also deposited on the front side 14, it must, if necessary, be removed and/or taken into account in further process steps.

Next, a conductive etch barrier layer 28 is formed on the first conductive layer 26, in particular on the backside 16 of the semiconductor substrate 12. This can be achieved by deposition. The conductive etch barrier layer 28 can comprise or consist essentially of a conductive material, such as a metal, a conductive metal oxide, titanium nitride, or silicon carbide. The conductive etch barrier layer 28 can also be or comprise a layer stack (e.g., a plurality of layers) on the backside 16 of the semiconductor substrate 12. The conductive etch barrier layer 28 serves as an etch barrier against an alkaline etch in a subsequent process step. The conductive etch barrier layer 28 may also cover the front side 14 completely or partially, for example at the edges. Any conductive etch barrier layer 28 on the front side 14 is not shown but must, if necessary, be taken into account and/or removed in further process steps.

FIG. 5 shows the semiconductor substrate 12 with the first tunnel layer 24, the first conductive layer 26, and the conductive etch barrier layer 28 on the back side 16 of the semiconductor substrate 12, and a fourth conductive layer 42 on the front side 14 of the semiconductor substrate 12.

After forming the conductive etch barrier layer 28, it is removed in a plurality of etch areas 50 (see FIG. 6). This can be implemented, for example, by laser ablation. The ablation width can range between 10 μm and 2000 μm, or any value or range of values therein (e.g., 50 μm to 1000 μm). The spacing (center-to-center) between two etch areas 50 can range between 100 um and 3000 μm. The ablation can be carried out in a linear manner and result in a so-called “interdigitated” pattern. This pattern can be interrupted in locations of current collection busbars on the solar cell 10. During the removal of the conductive etch barrier layer 28 in the etch areas 50, the first conductive layer 26 and/or the first tunnel layer 24 may also be partially or completely removed. In addition, the semiconductor substrate 12 may also be partially removed on its back side 16.

Alternatively, the conductive etch barrier layer 28 can patterned during deposition (that is, applied to the first conductive layer 26 with interruptions or openings in the etch areas 50). This can, for example, be achieved by deposition through a mask or by a printing process.

Subsequently, the etching areas 50 are etched, during which under-etching (e.g., lateral etching of material[s] below the conductive etch barrier layer 28) creates the pedestal-like elevations 38 and third areas 22 (see FIG. 6). The first areas 18 are on the elevations 38. The second areas 20 are between the elevations 38, or more particularly, between adjacent third areas 22 on opposite sides of an etching area 50. In this case, in particular, the first conductive layer 26, the first tunnel layer 24, and part of the semiconductor substrate 12 on the back side 16 are removed in the second areas 20 by etching. The etching can comprise wet chemic etching with an acidic or alkaline solution or dry etching, which, for example, can remove silicon isotropically or anisotropically. In this etching step, the materials below the conductive etch barrier layer 28 are at least partially etched, creating undercut areas below outer edges of the conductive etch barrier layer 28, resulting in the third areas 22, which are shadowed along the first (vertical) direction 40 by the conductive etch barrier layer 28. The first conductive layer 26, and optionally, the first tunnel layer 24 can also be undercut. The depth of the etched areas 50 is determined by the etch depth and can, for example, range between 0.5 μm and 20 μm.

Etching can be performed only on the backside 16 in a single-sided etching process.

In the next step, the second tunnel layer 32 is formed (see FIG. 7). The second tunnel layer 32 can be formed between (and optionally on sidewalls of) the pedestal-like elevations 38. The second tunnel layer 32 can be formed by deposition (e.g., directional deposition, if little or no second tunnel layer 32 is desired on sidewalls of the pedestal-like elevations 38) or growth (e.g., thermal growth, which generally results in the second tunnel layer 32 being on sidewalls of the pedestal-like elevations 38). The second tunnel layer 32 can be formed on the back side 16. Additionally, the second tunnel layer 32 can also be formed on the front side 14. The second tunnel layer 32 can saturate open bonds on the surface of the semiconductor substrate 12. The second tunnel layer 32 can have a layer thickness ranging from 5 to 200 Angstroms.

Subsequently, the second conductive layer 30 is formed (cf. FIG. 8). The second conductive layer 30 can be formed by deposition. The second conductive layer 30 can be deposited using a directional method, for example PVD. The second conductive layer 30 (e.g., p-type) has, in particular, a doping opposite or complementary to that of the first conductive layer 26 (e.g., n-type). Due to the shadowing (with respect to the first direction 40) of the third regions 22 by the conductive etch barrier layer 28, the second conductive layer 30 is not formed (or only minimally formed in the case of a non-ideal directional deposition) in the third regions 22. Thus, the third regions 22 contain particularly no or only a minimal amount of the second conductive layer 30. In particular, due to the directional deposition (parallel and opposite to the first direction 40), little or no material of the second conductive layer 30 is deposited in the third areas 22, as the third areas 22 are shadowed.

Alternatively, the second conductive layer 30 can be partially deposited in the third areas 22, since PVD (and similar processes) is not exclusively unidirectional. However, because the thickness of the second conductive layer 30 that may deposit in the third regions 22 is significantly lower than that in the second regions 20, and/or the second conductive layer 30 does not completely cover the third regions 22, insulation or a sufficiently high resistance remains in the third regions 22 to not significantly adversely affect the efficiency of the solar cell 10. If necessary, the second conductive layer 30 in the third region 22 can be removed or at least reduced to an extent so as to not adversely affect the efficiency of the solar cell 10.

The second conductive layer 30 is also deposited onto the conductive etch barrier layer 28 in the first regions 18. The thickness of the second conductive layer 30 can range from 10 nm to 400 nm. The second conductive layer 30 may have a dopant concentration between 1×10¹⁹ cm⁻³ and 2×10²¹ cm⁻³. Since the conductive etch barrier layer 28 does not act as an insulator, charge carriers (e.g., an electric current) can flow with low resistance over the etch barrier layer 28 from the first conductive layer 26 into the second conductive layer 30 and vice versa. In particular, due to the directionality of its deposition, the second conductive layer 30 is not deposited on the front side 14. A high-temperature step for the crystallization of the first and/or second conductive layer 26, 30, as well as for the activation of the dopants in the first and/or second conductive layer 26, 30, can follow.

Next, a dielectric layer 44 can be deposited to passivate the surface of the front side 14 and the back side 16 (cf. FIG. 9). The dielectric layer 44 can consist of one or more layers, for example of an aluminum oxide, a silicon oxide, and/or silicon nitride. In various embodiments, the dielectric layer 44 on the front side 14 may include two layers, and the dielectric layer 44 on the back side 16 may consists of a single layer.

The dielectric layer 44 on the front side 14 and the dielectric layer 44 on the back side 16 can be identical or different, and in particular. may have different properties. A wet chemical cleaning step may precede the deposition of the dielectric layer 44. Any hydrogen in the dielectric layer can serve to saturate open bonds on the surface of the semiconductor substrate 12, and particularly on the surfaces of the first and second conductive layers 26, 30 in the first and second regions 18, 20, respectively. The dielectric layer 44 can also, in particular on the front side 14, serve as an antireflection coating and increase the light yield of the solar cell 10.

Subsequently, the first and second electrodes 34, 36 can be formed and/or applied (cf. FIG. 10). Each first electrode 34 contacts a second conductive layer 30 in a first region 18. Each second electrode 36 contacts a second conductive layer 30 in a second region 20.

For the electrodes 34, 36 to contact the second conductive layer 30, the dielectric layer 44 can have first and second interruptions 46, 48 at corresponding locations in the first and second regions 18 and 20. The implementation of the interruptions 46, 48 can, for example, be carried out by local ablation, such as laser irradiation. A conductive metal paste can also be used in the formation of the electrodes 34, 36 (e.g., by screen printing). The first and/or second interruptions 46, 48 can also be generated while firing the paste, by locally dissolving, melting or otherwise breaking through the dielectric layer 44. The firing step can also have a positive effect on the passivation of the non-metallized surfaces, since hydrogen in the dielectric layer 44 (if any) can mobilize during the high-temperature step, diffuse to the surface(s) of the semiconductor substrate 12, and saturate open bonds there.

The first and/or second interruptions 46, 48 can be continuous (e.g., lines) or interrupted, in the form of circles, ovals, squares, rectangles or segmented lines. The paste can, for example, contain silver, copper, and/or aluminum as the conductive metal(s). After firing, the particles in the paste sinter (e.g., bind together) and form the first and second electrodes 34, 36. The first and/or second electrodes 34, 36 may also comprise a layer stack (paste stack), for example, comprising silver and copper. When using aluminum, the composition of the paste can be selected so that the aluminum alloys minimally or not at all with silicon. Such a composition is suitable for contacts of both polarities.

### Reference List

10: Solar cell; 12: Semiconductor substrate; 14: Front side; 16: Back side; 18: First region; 20: Second region; 22: Third region; 24: First tunnel layer; 26: First conductive layer; 28: Conductive etch barrier layer; 30: Second conductive layer; 32: Second tunnel layer; 34: First electrode; 36: Second electrode; 38: Pedestal-like elevation; 40: First direction; 42: Fourth conductive layer; 44: Dielectric layer; 46: First interruption; 48: Second interruption; 50: Etching region.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

What is claimed is:

1. A back-contact solar cell comprising:
a semiconductor substrate with a front side and a back side,
a plurality of first electrodes; and
a plurality of second electrodes, wherein:
the back side comprises a plurality of first regions, a plurality of second regions, and a plurality of third regions;
the first regions comprise a first tunnel layer, a first conductive layer, a conductive etch barrier layer, and a second conductive layer;
the second regions comprise a second tunnel layer and a second conductive layer;
the first regions and the second regions each form passivating contacts;
the third regions comprise under-etched regions of the conductive etch barrier layer;
each first electrode is in a first region and contacts a second conductive layer;
each second electrode is in a second region and contacts the second conductive layer; and
the first regions are on a pedestal-like elevation.

2. The back-contact solar cell according to claim 1, wherein the third regions are undoped.

3. The back-contact solar cell according to claim 1, wherein the third regions each comprise a third conductive layer.

4. The back-contact solar cell according to claim 1, further comprising a fourth conductive layer on the front side.

5. The back-contact solar cell according to claim 1, wherein the first conductive layers have a first doping type, and the second conductive layers have a second doping type complementary to the first doping type.

6. The back-contact solar cell according to claim 1, wherein the first conductive layers, the second conductive layers, the first tunnel layers and/or the second tunnel layers are each free of breaks.

7. The back-contact solar cell according to claim 1, wherein the first conductive layers, the second conductive layers, the third conductive layers, and/or the fourth conductive layer each comprise silicon, silicon carbide, and/or a conductive metal oxide.

8. The back-contact solar cell according to claim 1, wherein the first conductive layers and/or the second conductive layers each comprise amorphous, semi-crystalline, or polycrystalline silicon.

9. The back-contact solar cell according to claim 1, wherein the second conductive layers are configured to induce a ribbon bending in the semiconductor substrate, wherein on each of the second conductive layers an additional conductive layer is arranged, which has a higher conductivity than the respective second conductive layer positioned beneath it, in order to improve the conductivity.

10. The back-contact solar cell according to claim 1, wherein the conductive etch barrier layer comprises a metal, a metal oxide, titanium nitride, or silicon carbide.

11. The back-contact solar cell according to claim 1, further comprising a first dielectric layer or a first stack of dielectric layers on the front side as an outermost layer.

12. The back-contact solar cell according to claim 1, further comprising a second dielectric layer or a second stack of dielectric layers on the second conductive layer on the back side.

13. The back-contact solar cell according to claim 12, wherein the second dielectric layer or the second stack of dielectric layers comprises, in the first areas, a first opening and, in the second areas, a second opening, and the back-contact solar cell further comprises a first electrode that contacts a second conductive layer through the first opening, and a second electrode that contacts the second conductive layer through the second opening.

14. A method for manufacturing a back-contact solar cell, comprising:
forming a first tunnel layer on a back side of a semiconductor substrate;
forming a first conductive layer on the first tunnel layer;
forming a conductive etch barrier layer on the first conductive layer, wherein the conductive etch barrier layer has interruptions in a plurality of etch regions;
etching in the etch regions and at least partially underetching the conductive etch barrier layer, thereby generating pedestal-like elevations and third regions;
forming a second tunnel layer in areas between the pedestal-like elevations;
forming a second conductive layer in the areas between the pedestal-like elevations, but not in the third regions due to the conductive etch barrier layer.

15. The method according to claim 14, further comprising forming a third conductive layer in the third regions and/or a fourth conductive layer on the front side by furnace diffusion.

16. The method according to claim 15, further comprising removing a silicate glass layer formed during the furnace diffusion by etching.

17. The method according to claim 14, further comprising forming a dielectric layer or a stack of dielectric layers on the back side and/or on a front side of the semiconductor substrate.

18. The method according to claim 14, further comprising forming first electrodes and/or second electrodes on the back side.

19. The method according to claim 14, wherein, after forming the conductive etch barrier layer, the method comprises removing the conductive etch barrier layer in the plurality of etch regions.
